(19) United States
(12) Patent Application Publication
(10) Pub. No.: US 2024/0217309 A1
(43) Pub. Date: Jul. 4, 2024

(54) VEHICLE

(71) Applicant: TOYOTA JIDOSHA KABUSHIKI KAISHA, Toyota-shi, Aichi-ken (JP)

(72) Inventor: Noriyuki YAMANAKA, Nagoya-shi (JP)

(73) Assignee: TOYOTA JIDOSHA KABUSHIKI KAISHA, Toyota-shi, Aichi-ken (JP)

(21) Appl. No.: 18/463,564

(22) Filed: Sep. 8, 2023

(30) Foreign Application Priority Data
Dec. 28, 2022 (JP) 2022-212312

(51) Int. Cl. B60H 1/24; B60L 50/60

(52) U.S. Cl. CPC B60H 1/246; B60L 50/60

(57) ABSTRACT

The vehicle of the present disclosure includes an in-vehicle device that includes a housing to which cooling air is supplied and is supported by a vehicle body, and includes a ventilation duct that is held by the housing and the interior component so as to communicate with the interior of the housing of the in-vehicle device and an opening formed in the interior component, and a duct fixing member that is formed by the elastic body and holds a part of the ventilation duct and is fitted to the vehicle body.

### CROSS-REFERENCE TO RELATED APPLICATION

This application claims priority to Japanese Patent Application No. 2022-212312 filed on Dec. 28, 2022, incorporated herein by reference in its entirety.

### BACKGROUND

### 1. Technical Field

The present disclosure relates to a vehicle.

### 2. Description of Related Art

A related-art electrified vehicle includes a battery disposed below a rear seat disposed behind a driver's seat, and a heat duct extending from the battery (see, for example, Japanese Unexamined Patent Application Publication No. 2021-014234 (JP 2021-014234 A)). In this electrified vehicle, an inter-wall space is defined by a side trim serving as a side surface of a vehicle cabin on an outer side of the rear seat in a vehicle width direction and a side body serving as an outer side surface of the vehicle. The inter-wall space is divided into an upper space and a lower space by a partition wall. Exhaust gas generated by the battery is guided to the lower space by the heat duct.

### SUMMARY

However, J P 2021-014234 A does not disclose a specific holding structure of the duct. Therefore, in the electrified vehicle described in JP 2021-014234 A, the duct may be detached from the side trim or the like or abnormal noise may occur when the duct is vibrated.

In view of the above, it is a main object of the present disclosure to appropriately regulate the position of a ventilation duct connected to a housing of an in-vehicle device to suppress a positional deviation of the ventilation duct and the occurrence of abnormal noise.

A vehicle according to the present disclosure includes an in-vehicle device including a housing having an inside to which cooling air is supplied and supported by a vehicle body. The vehicle includes: a ventilation duct held by the housing and an interior component to communicate with the inside of the housing of the in-vehicle device and an opening in the interior component; and a duct fixing member that is made of an elastic body, holds a part of the ventilation duct, and is fitted to the vehicle body.

In the vehicle of the present disclosure, the ventilation duct is held by the housing of the in-vehicle device and the interior component of the vehicle, and communicates with the inside of the housing and the opening in the interior component. A part of the ventilation duct is held by the duct fixing member made of the elastic body, and the duct fixing member is fitted to the vehicle body. Therefore, the duct fixing member appropriately regulates the position of the ventilation duct connected to the inside of the housing of the in-vehicle device and the opening in the interior component. Thus, in the vehicle of the present disclosure, it is possible to satisfactorily suppress the positional deviation of the ventilation duct and the occurrence of abnormal noise when the ventilation duct is vibrated.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a schematic configuration diagram showing a vehicle of the present disclosure;

FIG. 2 is a schematic configuration diagram showing a vehicle of the present disclosure;

FIG. 3 is a plan view illustrating a main part of the vehicle of the present disclosure; and

FIG. 4 is an enlarged view showing a main part of disclosed vehicles.

### DETAILED DESCRIPTION OF EMBODIMENTS

Next, embodiments of the present disclosure will be described with reference to the drawings.

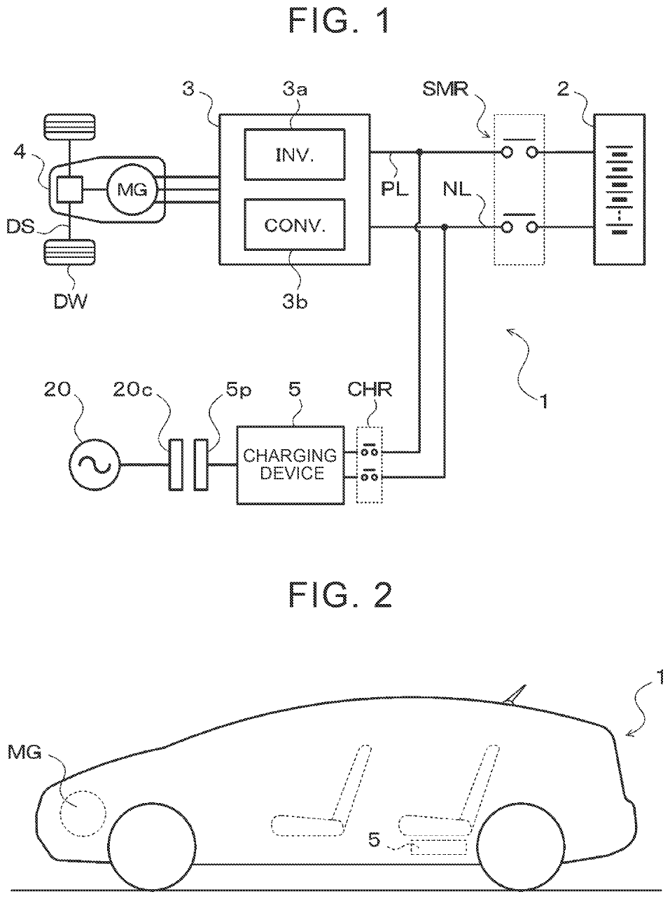

FIG. 1 and FIG. 2 are schematic structural diagrams showing a vehicle 1 of the present disclosure. The vehicle 1 shown in these drawings are battery electric vehicle (BEV) including a motor generator MG, a battery (high-voltage battery) 2, a system main relay SMR, and a power control device (hereinafter referred to as “PCU”) 3. The vehicle 1 may be a front-wheel drive vehicle, a rear-wheel drive vehicle, or a four-wheel drive vehicle.

The battery 2 includes a plurality of battery modules connected in series and a battery case that houses the plurality of battery modules. The battery 2 is mounted under the floor of the vehicle 1 (below the floor panel of the vehicle body) in the vicinity of the rear seat Sr (see FIG. 2), for example. Each battery module of the battery 2 includes a plurality of battery cells (not shown) connected in series or in parallel. Each battery cell is, for example, a lithium-ion secondary battery or a nickel-hydrogen secondary battery. The positive electrode side power line PL is connected to the positive electrode terminal of the battery 2 via the positive electrode side relay of the system main relay SMR. The negative electrode side power line NL is connected to the negative electrode terminal of the battery 2 via the negative electrode side relay of the system main relay SMR.

PCU3 is connected to the battery 2 via the positive electrode side power line PL, the negative electrode side power line NL, and the system main relay SMR. PCU3 includes an inverter (drive circuit) 3a that drives the motor generator MG, a step-up converter 3b that can step up the power from the battery 2 and step down the voltage from the motor generator MG, and a chargeable/dischargeable capacitor (not shown).

The motor generator MG is a synchronous generator motor (three-phase alternating current (AC) motor). The rotor of the motor generator MG is coupled to the drive wheel DW via a power transmission including a speed reducer and a differential gear coupled to the drive shaft DS. The motor generator MG is driven by electric power from PCU3 (battery 2) and outputs a driving torque (driving force) to the drive shaft DS, that is, the drive wheels DW. Further, the motor generator MG outputs regenerative braking torque to the drive shaft DS at the time of braking of the vehicle 1. In the present embodiment, the motor generator MG, the speed reducer, and the differential gear form the transaxle 4 together with the transaxle case that houses them.

Further, the vehicle 1 includes a charging device (AC charger) 5, which is an in-vehicle device for charging the battery 2 with electric power from an AC power source 20 outside the vehicle, such as a household power source. The charging device 5 includes a AC/direct current (DC) converter that converts AC power into DC power, a DC/DC converter that boosts the DC power outputted from AC/DC converter, and a charging control device that controls these electric devices (both of which are not shown).

AC/DC converters of the charging device 5 are connected to an outlet-plug 5p which can be coupled to an outlet 20c of the AC power supply 20. DC/DC converters of the charging device 5 are connected to the positive electrode side power line PL and the negative electrode side power line NL between the system main relay SMR and PCU3 via the charging relay CHR. The charging control device of the charging device 5 operates AC/DC converters and DC/DC converters with the outlet plug 5p coupled to the outlet 20c and with the system main relay SMR and the charging relay CHR closed. As a result, the battery 2 is charged by the electric power (AC electric power) from the AC power supply 20.

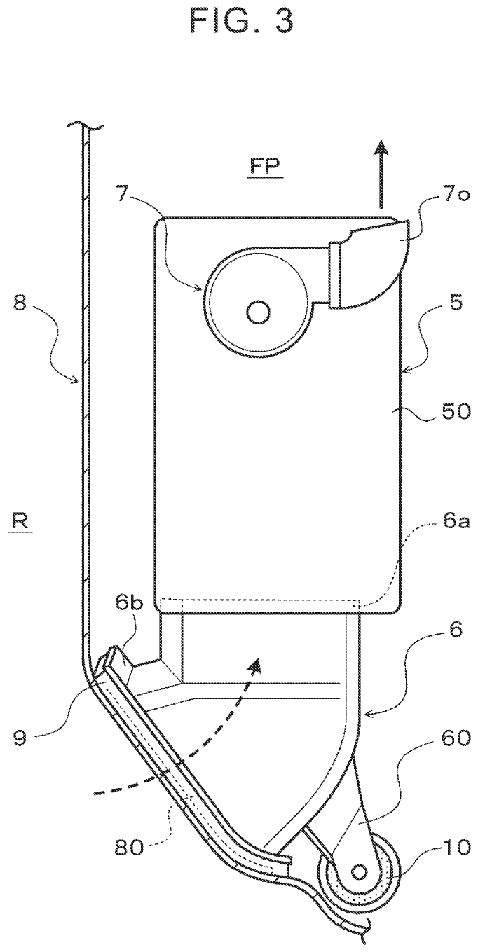

As shown in FIG. 2, the charging device 5 is disposed in a space defined below the rear seat Sr disposed behind the front row seat (driver's seat) Sf of the vehicle 1. The charging device 5 includes a housing 50 that houses AC/DC converter, DC/DC converter, the charging control device, and the like. As shown in FIG. 3, the housing 50 of the charging device 5 is fixed to the floor panel FP of the vehicle body via a bolt or the like (not shown). A ventilation duct 6 and a blower 7 are connected to the housing 50.

The ventilation duct 6 is, for example, a cylindrical body made of resin or metal, and is held by a housing 50 of the charging device 5 and an interior component (trim) 8 that partitions a space below the rear seat Sr of the vehicle 1 and an inside of the vehicle cabin R. That is, as shown in FIG. 3, one end 6a of the ventilation duct 6 is fitted into the housing 50 of the charging device 5, and the inside of the ventilation duct 6 communicates with the inside of the housing 50. Further, the other end 6b of the ventilation duct 6 is pressed against the interior component 8 via an elastic ring-shaped (square tube-shaped) seal member (Ept seal) 9. An opening 80 communicating with the inside of the ventilation duct 6 is formed in the interior component 8, and filters (not shown) are disposed in the opening 80. As a result, the inside of the ventilation duct 6 communicates with the inside of the vehicle cabin R via the opening 80 (filters).

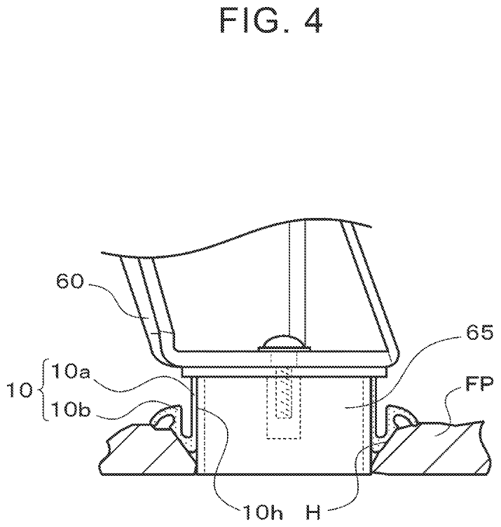

The ventilation duct 6 also includes a supported portion 60 extending from the cylindrical body as shown in FIGS. 3 and 4. The supported portion 60 is supported from below by a floor panel FP of the vehicle body via a grommet 10 serving as a duct fixing member. The grommet 10 is made of, for example, an elastic body such as rubber or resin. The grommet 10 includes a main body 10a formed in a cylindrical shape, and a lip portion 10b extending radially outward from one end of the main body 10a and toward the other end. As shown in FIG. 4, a bottomed cylindrical seal member 65 is fixed to the supported portion 60 via a bolt or the like. The seal member 65 is fitted (press-fitted) into the center hole 10h of the main body 10a. Then, the grommet 10, i.e., the lip portion 10b, is fitted (press-fitted) to the rear portion H formed on the floor panel FP.

When the charging device 5 is operated, that is, when the battery 2 is charged by electric power from the AC power source 20, the blower 7 sucks the air inside the housing 50 and discharges the air from the discharge port 70 into the storage space of the charging device 5. With the operation of the blower 7, the air in the vehicle cabin R is sucked into the housing 50 of the charging device 5 through the ventilation duct 6 and the opening 80 as the intake duct (see a broken line arrow in FIG. 3). Air sucked into the housing 50 removes heat from AC/DC converters, DC/DC converters, and the like, and is discharged from the discharge port 70 of the blower 7 into the storage space (see solid arrows in FIG. 3). Thus, when the battery 2 is charged by the electric power from the AC power supply 20, the charging device 5 can be cooled.

As described above, in the vehicle 1, the ventilation duct 6 is held by the housing 50 of the charging device 5 and the interior component 8, and communicates with the opening 80 formed in the interior of the housing 50 and the interior component 8. That is, one end 6a of the ventilation duct 6 is fitted to the housing 50 of the charging device 5. The other end 6b of the ventilation duct 6 is pressed against the interior component 8 via an elastic seal member 9. Further, the supported portion 60 of the ventilation duct 6 is held by a grommet 10 as a duct fixing member formed of an elastic body. The grommet 10 is fitted (press-fitted) to the floor panel FP of the vehicle body. As a result, the grommet 10 restricts the position of the ventilation duct 6 connected to the inside of the housing 50 of the charging device 5 and the opening 80 of the interior component 8 in the front-rear direction, the widthwise direction, and the height direction of the vehicle 1.

Therefore, in the vehicle 1, when the ventilation duct 6 is vibrated during traveling or the like, it is possible to satisfactorily suppress generation of abnormal noise. Further, in the vehicle 1, when the ventilation duct 6 is vibrated during traveling or the like, it is possible to satisfactorily suppress the positional deviation between the ventilation duct 6 and the interior component 8 (opening 80). Thus, it is possible to prevent air from being sucked from the accommodation space of the charging device 5 through the gap between the ventilation duct 6 and the interior component 8 by the blower 7, and to ensure good air blowing efficiency in the housing 50.

Further, the grommet 10 formed of rubber or resin appropriately regulates the position of the ventilation duct 6 while ensuring the assembling property of the ventilation duct 6, and can satisfactorily suppress the positional deviation of the ventilation duct 6 and the generation of abnormal noise. Further, in the above-described embodiment, the grommet 10 is fitted to the floor panel FP and supports the ventilation duct 6 from below. Accordingly, since the ventilation duct 6 can be supported while being floated with respect to the floor panel FP, generation of abnormal noise can be satisfactorily suppressed when the ventilation duct 6 is vibrated.

In the vehicle 1, the ventilation duct 6 may communicate with an inter-wall space (air passage) defined by an outer plate of the vehicle body and an interior component (side trim). In this case, the blower 7 may introduce the air sucked from the storage space of the charging device 5 into the housing 50. The ventilation duct 6 may be used as an exhaust duct for discharging the air in the housing 50 into the inter-wall space. In addition, the present disclosure may be applied to an in-vehicle device (for example, a battery) other than the charging device as long as it has a housing in which cooling air is supplied. Further, the vehicle 1 may be a hybrid electric vehicle (HEV, PHEV) including an engine in addition to the motor generator MG, or may be a vehicle including only an engine as a driving power generation source.

As described above, the vehicle of the present disclosure is a vehicle (1) including an in-vehicle device (5) having a housing (50) to which cooling air is supplied and supported by a vehicle body (FP), wherein the vehicle includes a ventilation duct (6) held by the housing (50) and the interior component (8) so as to communicate with the inside of the housing (50) of the in-vehicle device (5) and an opening (80) formed in the interior component (8), and a duct fixing member (10) formed by an elastic body and holding a part (60) of the ventilation duct (6) and fitted to the vehicle body (FP).

In the vehicle of the present disclosure, the ventilation duct is held by the housing of the in-vehicle device and the interior component of the vehicle, and communicates with the inside of the housing and the opening formed in the interior component. Further, a part of the ventilation duct is held by a duct fixing member formed of an elastic body, and the duct fixing member is fitted to the vehicle body. Accordingly, the duct fixing member appropriately regulates the position of the ventilation duct connected to the inside of the housing of the in-vehicle device and the opening of the interior component. Therefore, in the vehicle of the present disclosure, when the ventilation duct is vibrated, it is possible to satisfactorily suppress the positional deviation of the ventilation duct and the occurrence of abnormal noise.

The duct fixing member may be a grommet (10) made of rubber or resin.

According to this aspect, the position of the ventilation duct is restricted in the front-rear direction, the width direction, and the height direction of the vehicle while ensuring the assembling property of the ventilation duct satisfactorily, and the positional deviation of the ventilation duct and the occurrence of abnormal noise can be suppressed satisfactorily.

The grommet (10) may be fitted to a floor panel (FP) of the vehicle body and may support the ventilation duct from below.

Such an aspect enables the ventilation duct to be supported in a state of being floated with respect to the vehicle body, and satisfactorily suppresses generation of abnormal noise when the ventilation duct is vibrated.

One end (6a) of the ventilation duct (6) may be fitted to the housing (50) of the in-vehicle device (5), and the other end (6b) of the ventilation duct (6) may be pressed against the interior component (8) via an elastic seal member (9).

Such an aspect further improves the assemblability of the ventilation duct.

The vehicle (1) may include an electric motor (MG) for outputting a driving force to a drive wheel (DW) and a battery (2) for supplying electric power to the electric motor (MG), and the in-vehicle device may be a charging device (5) used for charging the battery (2) by electric power from an external power supply (20), and may be disposed below a rear seat (Sr) disposed behind a front row seat (Sf) of the vehicle (1), and the interior component (8) may partition a space below the rear seat (Sr) and a vehicle cabin (R).

It is needless to say that the present disclosure is not limited to the above-described embodiments, and various modifications can be made within the scope of the extension of the present disclosure. Furthermore, the above-described embodiment is only a specific form of the disclosure described in the column of the outline of the disclosure, and does not limit the elements of the disclosure described in the column of the outline of the disclosure.

The present disclosure can be used in a vehicle manufacturing industry and the like.

What is claimed is:

1. A vehicle including an in-vehicle device including a housing having an inside to which cooling air is supplied and supported by a vehicle body, the vehicle comprising:
a ventilation duct held by the housing and an interior component to communicate with the inside of the housing of the in-vehicle device and an opening in the interior component; and
a duct fixing member that is made of an elastic body, holds a part of the ventilation duct, and is fitted to the vehicle body.

2. The vehicle according to claim 1, wherein the duct fixing member is a grommet made of rubber or resin.

3. The vehicle according to claim 2, wherein the grommet is fitted to a floor panel of the vehicle body and supports the ventilation duct from a bottom.

4. The vehicle according to claim 3, wherein one end of the ventilation duct is fitted to the housing of the in-vehicle device, and another end of the ventilation duct is pressed against the interior component via an elastic seal member.

5. The vehicle according to claim 1, further comprising:
an electric motor configured to output a driving force to a driving wheel; and
a battery configured to supply electric power to the electric motor, wherein:
the in-vehicle device is a charging device to be used to charge the battery with electric power from an external power supply, and is disposed below a rear seat disposed behind a front row seat of the vehicle; and
the interior component partitions a space below the rear seat and a vehicle cabin.
